(19) United States
(12) Patent Application Publication
(10) Pub. No.: US 2015/0060976 A1
(43) Pub. Date: Mar. 5, 2015

(54) NON-VOLATILE STORAGE DEVICE AND MANUFACTURING METHOD THEREOF

(71) Applicant: Kabushiki Kaisha Toshiba, Tokyo (JP)

(72) Inventor: Tadashi IGUCHI, Mie (JP)

(73) Assignee: KABUSHIKI KAISHA TOSHIBA, Tokyo (JP)

(21) Appl. No.: 14/194,779

(22) Filed: Mar. 2, 2014

(30) Foreign Application Priority Data
Sep. 5, 2013 (JP) 2013-184252

(51) Int. Cl. H01L 27/115

(52) U.S. Cl. CPC H01L 27/11551; H01L 27/11578
USPC 257/314; 438/270

(57) ABSTRACT

According to an embodiment, a solid state storage device includes a first gate; a plurality of conductive layers having insulating layers therebetween, one of the insulating layers located on the first gate, an interconnection region extending inwardly of the first gate, a first semiconductor layer extending through the plurality of conductive layers and insulating layers, a second semiconductor layer extending through the plurality of conductive layers and insulating layers; a third semiconductor layer extending through the interconnection region and electrically connecting the first and second semiconductor layers, and an insulator extending through the plurality of conductive layers and insulating layers at a location intermediate of the first and second semiconductor layers, and also extending inwardly of the interconnection region.

### CROSS-REFERENCE TO RELATED APPLICATION

This application is based upon and claims the benefit of priority from Japanese Patent Application No. 2013-184252, filed Sep. 5, 2013, the entire contents of which are incorporated herein by reference.

### FIELD

An exemplary embodiment described herein relates generally to a non-volatile storage device and a manufacturing method thereof.

### BACKGROUND

Development of a non-volatile storage device where memory cells are arranged three dimensionally is ongoing in the solid state memory industry. One structure that is used includes a silicon substrate, a plurality of word lines which are stacked on the silicon substrate, and memory cell strings which vertically penetrate these word lines. It is desirable for a non-volatile storage device having such a structure that the number of memory cells formed along the memory cell string be increased. To achieve this, the number of stacked layers of word lines must be increased to increase the memory capacity, i.e., the number of memory cells, of this structure. Under such circumstances, for example, there has been a trend where controlling the depth of the features in which the memory cells are formed has become more difficult.

### DESCRIPTION OF THE DRAWINGS

FIG. 1 is a perspective view schematically depicting a non-volatile storage device according to an embodiment.

FIG. 2 is a schematic cross-sectional view of the non-volatile storage device according to the embodiment.

FIG. 3A to FIG. 3D are schematic cross-sectional views showing the results of steps of manufacturing the non-volatile storage device according to the embodiment.

FIG. 4A and FIG. 4B are schematic cross-sectional views showing the results of steps of manufacturing the non-volatile storage device which follow the steps shown in FIG. 3A to FIG. 3D.

FIG. 5A and FIG. 5B are schematic cross-sectional views showing the results of steps of manufacturing the non-volatile storage device which follow the steps shown in FIG. 4A and FIG. 4B.

FIG. 6A and FIG. 6B are schematic cross-sectional views showing the results of steps of manufacturing the non-volatile storage device which follow the steps shown in FIG. 5A and FIG. 5B.

FIG. 7A and FIG. 7B are schematic cross-sectional views showing the results of steps of manufacturing the non-volatile storage device which follow the steps shown in FIG. 6A and FIG. 6B.

FIG. 8A and FIG. 8B are schematic cross-sectional views showing the results of steps of manufacturing the non-volatile storage device which follow the steps shown in FIG. 7A and FIG. 7B.

### DETAILED DESCRIPTION

According to an embodiment, there is provided a non-volatile storage device which may absorb irregularities occurring during etching features thereof by increasing a thickness of a connection portion which connects memory holes arranged adjacent to each other thus facilitating the formation of the memory holes, and a method of manufacturing the same.

In general, according to one embodiment, a solid state storage device includes a first gate; a plurality of conductive layers having insulating layers therebetween, one of the insulating layers located on the first gate, an interconnection region extending inwardly of the first gate, a first semiconductor layer extending through the plurality of conductive layers and insulating layers, a second semiconductor layer extending through the plurality of conductive layers and insulating layers; a third semiconductor layer extending through the interconnection region and electrically connecting the first and second semiconductor layers, and an insulator extending through the plurality of conductive layers and insulating layers at a location intermediate of the first and second semiconductor layers, and also extending inwardly of the interconnection region.

Hereinafter, an embodiment is explained with reference with drawings. In the drawings, identical parts are given the same symbols, and a detailed explanation thereof is omitted when it is not necessary, and an explanation is made with respect to features which differ from each other. The drawings are schematic or conceptual views and hence, the relationship between a thickness and a width of each part, a ratio between sizes of portions and the like are not always equal to those of an actually used device. Further, even when the same portion of a device or structure is shown, there may be a case where the part is expressed in different sizes or ratios depending on the drawings.

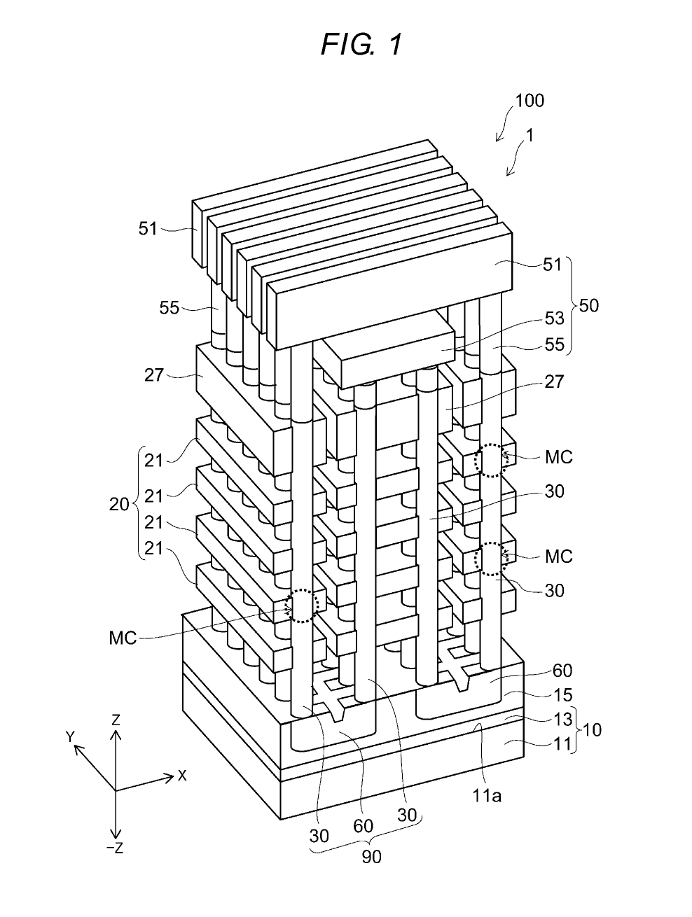

FIG. 1 is a perspective view schematically showing a non-volatile storage device 100 according to the embodiment. The non-volatile storage device 100 according to the embodiment is a so-called NAND-type flash memory, and includes a memory cell array 1 where memory cells are arranged three-dimensionally.

FIG. 1 is a perspective view showing apart of the memory cell array 1. To facilitate the understanding of the structure of the memory cell array 1, the description of insulation films is omitted. That is, respective elements of the memory cell array 1 are insulated from each other by insulation films which surround the structures shown in FIG. 1.

As shown in FIG. 1, the non-volatile storage device includes the memory cell array 1 which is mounted on a underlying layer 10.

The underlying layer 10 includes a substrate 11 and an interlayer insulation film 13 formed on the substrate 11, for example. The substrate 11 is a silicon wafer, for example, and circuitry and control devices such as transistors which controls the memory cell array 1 are mounted on an upper surface 11a of the substrate 11. The interlayer insulation film 13 is formed on the substrate 11. The memory cell array 1 is mounted on the interlayer insulation film 13.

The memory cell array 1 includes: a first conductive layer (hereinafter referred to as a back gate layer 15) formed on the interlayer insulation film 13; stacked bodies 20 which are mounted on the back gate layer 15, a second conductive layer (hereinafter referred to as a selector gate 27) which is mounted on the stacked bodies 20; and a wiring layer 50 which is formed on the selector gate 27. The stacked body 20 includes a plurality of conductive films (hereinafter referred to as word lines 21). The wiring layer 50 includes bit lines 51 and a source line 53.

In the explanation made hereinafter, assume the direction perpendicular to the upper surface 11a of the substrate 11 as the Z direction, assume one direction out of two directions orthogonal to the Z direction as the X direction, and assume the other direction out of two directions orthogonal to the Z direction as the Y direction. There may be also a case where the Z direction is expressed as the upward direction, and the −Z direction which is the direction opposite to the Z direction is expressed as the downward direction.

As shown in FIG. 1, the memory cell array 1 includes a plurality of stacked bodies 20. The plurality of stacked bodies 20 are arranged parallel to each other in the X direction. The plurality of word lines 21 included in the stacked body 20 extend in a stripe shape in the Y direction, and are stacked one over the other, in a spaced relationship, in the Z direction.

The selector gates 27 are located over, in the Z-direction, the stacked bodies 20 and extend as in the Y direction and are arranged parallel to, and spaced apart form, each other in the X direction. Semiconductor pillars 30 which penetrate the stacked bodies 20 and the selector gate 27 in the −Z direction (first direction) are provided.

Two semiconductor pillars 30 which respectively penetrate two stacked bodies 20 of word lines 21 and arranged adjacent to each other in the X direction are electrically connected to each other by a connection portion 60 located adjacent to substrate 11. An upper end of one of the two semiconductor pillars 30 is electrically connected to the bit line 51 (first line) via a contact plug 55, and an upper end of the other of the two semiconductor pillars 30 which are electrically connected at connector portion 60 is electrically connected to the source line 53 (second line). That is, a memory cell string 90 provided between the bit line 51 and the source line 53 includes the two semiconductor pillars 30 and the connection portion 60 which connects the two semiconductor pillars 30 to each other.

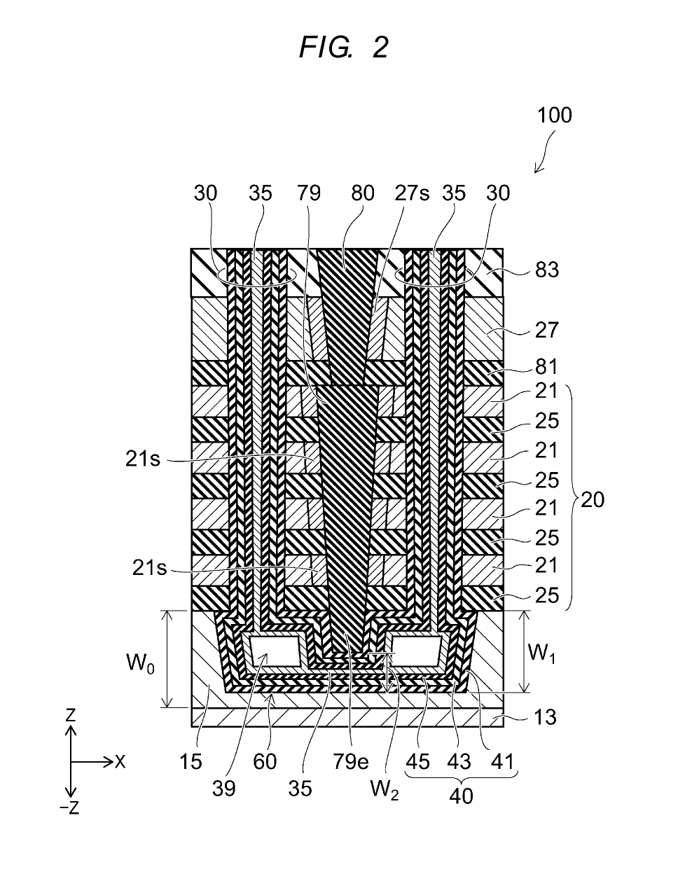

A memory film 40 is formed on outer surfaces of the semiconductor pillars 30 and the connection portion 60 (see FIG. 2). The memory film 40 provided between the semiconductor pillar 30 and the word line 21 functions as a charge storage film. That is, a memory cell MC is formed around each of the semiconductor pillars 30 at a location at each word line 21. A selection transistor is formed between the selector gate 27 and the semiconductor pillar 30. The memory film 40 functions as a gate insulation film for the selection transistor. The memory film 40 provided to the connection portion 60 functions as a gate insulation film for a back gate transistor.

FIG. 2 is a schematic cross-sectional view showing the non-volatile storage device 100 in detail.

As shown in FIG. 2, the non-volatile storage device 100 includes the back gate layer 15 and the plurality of stacked bodies 20 which are located over, and spaced from, the back gate layer 15 and one another in a state where the stacked bodies 20 extend in the Y direction (into the Figure) and are arranged parallel to each other.

The stacked bodies 20 includes the plurality of word lines 21 which are stacked on the back gate layer 15, and first insulation films (hereinafter, insulation films 25) each of which is provided between two word lines 21 arranged adjacent to each other out of the plurality of word lines 21.

The word line 21 is, for example, formed of a polycrystalline silicon (hereinafter, polysilicon) film doped with impurities, and the insulation film 25 located between each adjacent pair of word lines 21 and below the lowermost word line 21 is formed of a silicon oxide film. As shown in FIG. 2, when all of the films which electrically insulate the word lines 21 and the selector gates 27 formed on the word lines 21 from one another are made of the same material (for example, a silicon oxide film), it may be said that the respective constitutional elements are insulated from each other by one insulation film 80. That is, the respective constitutional elements are electrically insulated from each other via the insulation film 80. The insulation film 80 includes a portion (insulation film 25) provided between the back gate layer 15 and the word line 21, a portion (insulation film 25) formed between the word lines 21 arranged adjacent to each other, a portion (insulation film 79) provided between the stacked bodies 20 in the x direction arranged adjacent to, and spaced in the each other in the Z/−Z direction, a portion (insulation film 81) provided between the word line 21 and the selector gate 27, and a portion (insulation film 83) formed on the selector gate 27.

The plurality of word lines 21 and selector gates 27 are respectively formed of a polysilicon film, for example, and include silicided end portions 21s, 27s respectively.

The non-volatile storage device 100 includes the plurality of semiconductor pillars 30 which penetrate the selector gate 27 and the stacked bodies 20 and extend to the back gate layer 15, and the connection portions 60. The connection portions 60 are formed within the back gate layer 15, and each connection portion 60 electrically connects two semiconductor pillars 30 which respectively penetrate two stacked bodies 20 arranged adjacent to each other out of the plurality of stacked bodies 20.

Each of the plurality of semiconductor pillars 30 includes a semiconductor film 35 which extends along the extending direction (−Z direction) of the semiconductor pillar 30 and the memory film 40 which covers the periphery of, i.e., the sides of, the semiconductor film 35. The memory film 40 is provided between the stacked bodies 20 and the semiconductor film 35 along the span of the semiconductor film 35 through the stacked bodies 20.

The memory film 40 has the structure where a silicon oxide film 41, a silicon nitride film 43 and a silicon oxide film 45 are formed over each other in this order in the direction from the surface of the stacked bodies 20 to the surface of the semiconductor film 35, for example. The memory film 40 includes a charge storage part between a silicon oxide film 41 (first film) which is brought into contact with the stacked body 20 and a silicon oxide film 45 (second film) which is brought into contact with the semiconductor film 35. In this example, the charge storage part is formed of the silicon nitride film 43 or an interface between the silicon nitride film 43 and the silicon oxide film 45, for example.

On the other hand, the connection portion 60 includes a portion of the semiconductor film 35 which electrically connects two semiconductor pillars 30 to each other, and a portion of a memory film which is provided between the back gate layer 15 and a portion of the semiconductor film 35. That is, in the connection portion 60, the memory film 40 is provided between portions of the semiconductor film 35 and the back gate later 15.

In this embodiment, the insulation film 79, which is provided between two stacked bodies 20 in the X direction includes an end portion 79e which projects further, in the −Z direction, than the ends of the semiconductor pillars 30 extending through the two adjacent stacked bodies 20, and which extends there into contact with the connection portion 60. The end portion 79e is brought into contact with a portion of the memory film 40 included in the connection portion 60.

In this embodiment, a thickness Wo of the back gate layer 15 in the −Z direction is larger than a maximum thickness W₁ of the connection portion 60 in the −Z direction. The maximum thickness W₁ of the connection portion 60 is larger than depth to which the end portion 79e of the insulation film 79 in the −Z direction extends below (−Z direction) insulation film 25.

That is, the connection portion 60 is formed within the back gate layer 15 such that the back gate layer 15 covers a lower surface and side surfaces of the connection portion 60. An inverse channel may be formed in the interface between the memory film 40 and the semiconductor film 35 by applying a bias to the back gate layer 15 so that conductivity of the connection portion 60 may be controlled.

The thickness Wo of the back gate layer 15 and the maximum thickness W₁ of the connection portion 60 are set such that the connection portion 60 is not interrupted by the end portion 79e even in a state where the insulation film 79 projects in the −Z direction. As the result of such setting, a width W₂ in the −Z direction of a portion of the connection portion 60 formed between the end portion 79e of the insulation film 79 and the back gate layer 15 becomes smaller than a width in the −Z direction (maximum width W₁) of a portion of the connection portion 60 which is brought into contact with bases of the semiconductor pillars 30. The connection portion 60 is provided with a gap 39 surrounded by a portion of the semiconductor film 35.

In the −Z direction, the width W₂ between the end portion 79e of the insulation film 79 and the back gate layer 15 which faces the end portion 79e in an opposed manner is more than two times larger than a film thickness of the memory film 40. That is, after the memory film 40 is formed, it is possible to ensure a space between the end portion 79e of the insulation film 79 and the back gate layer 15. By forming a portion of the semiconductor film 35 in the space within the memory film 40 immediately below end portion 79e, two adjacent semiconductor pillars 30 may be electrically connected to each other using the semiconductor film 35 extending through the space.

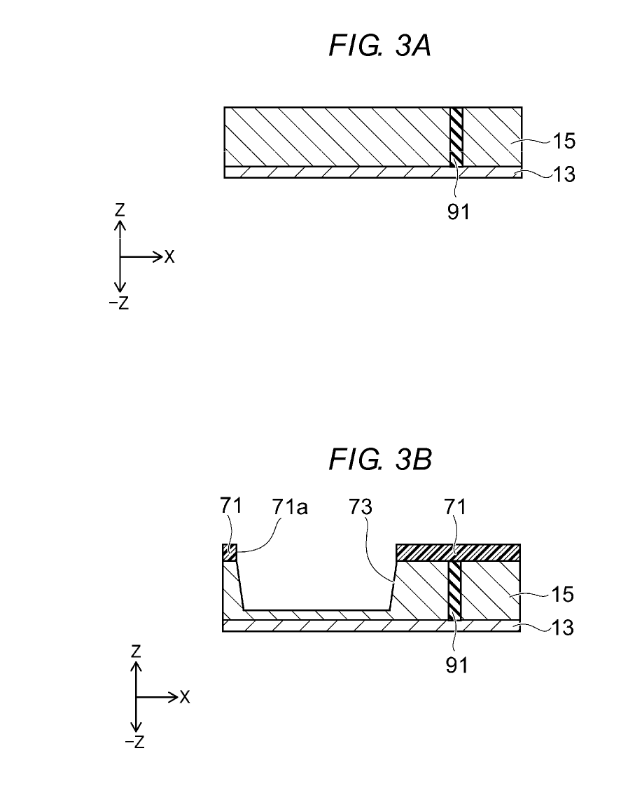

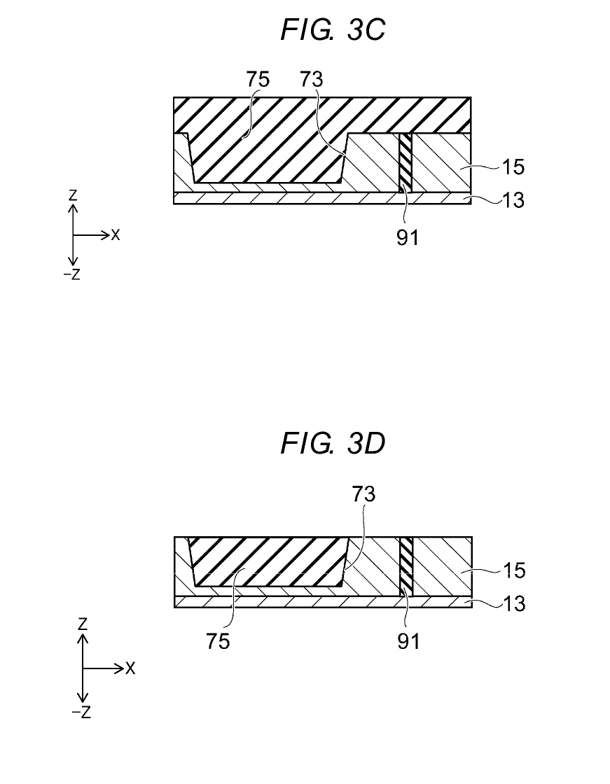

Next, a method of manufacturing the non-volatile storage device 100 according to the embodiment is explained with reference to FIG. 3A to FIG. 8B.

FIG. 3A to FIG. 8B are schematic cross-sectional views showing the physical result of a series of steps of manufacturing the non-volatile storage device 100 according to the embodiment.

As shown in FIG. 3A, the back gate later 15 is formed on the interlayer insulation film 13. The back gate layer 15 is formed of a p-type polysilicon layer doped with boron (B), for example. An insulation film 91 is embedded into the back gate layer 15. The insulation film 91 divides the back gate layer 15 in accordance into segments or units corresponding to a plurality of memory blocks included in the memory cell array 1.

Next, as shown in FIG. 3B, after a resist 71 layer is formed on the back gate layer 15 and the resist 71 is patterned to include an opening 71a formed, the back gate layer 15 is selectively etched by dry etching using the resist 71 as a mask thus forming a first groove 73. As described later, the first groove 73 is formed to have a depth such that the first groove 73 may absorb irregularities in processing a second groove 76 by which a conductive film 121 is divided and the connection portion 60 is not divided by an insulation film 77. That is, the first groove 73 is formed such that a bottom portion of the second groove 76 is positioned above a bottom surface of the first groove 73. Further, the thickness Wo of the back gate layer 15 is set larger than a depth of the first groove 73.

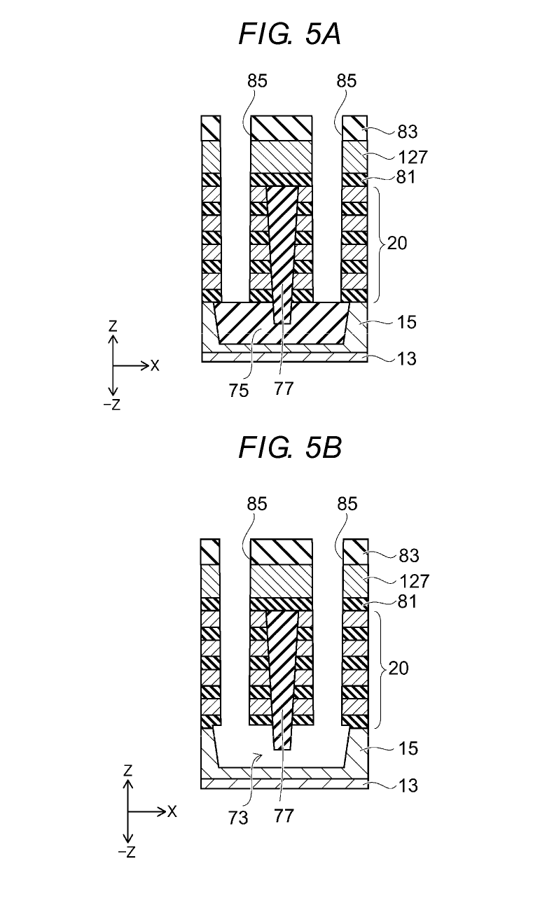

Next, the result of which is shown in FIG. 3C, a sacrificial film 75 is embedded into the first groove 73. The sacrificial film 75 has the selectivity to etching with respect to the back gate layer 15, the insulation film 25 and the insulation film 77 (see FIG. 5B), i.e., it etches preferentially compared to the back gate layer 15, the insulation film 25 and the insulation film 77. The sacrificial film 75 is formed of a non-doped polysilicon film, for example. Then, the whole surface of the sacrifice film 75 is etched back and, as shown in FIG. 3D, to expose the surface of the back gate layer 15 leaving the sacrifice film 75 embedded into the first groove 73.

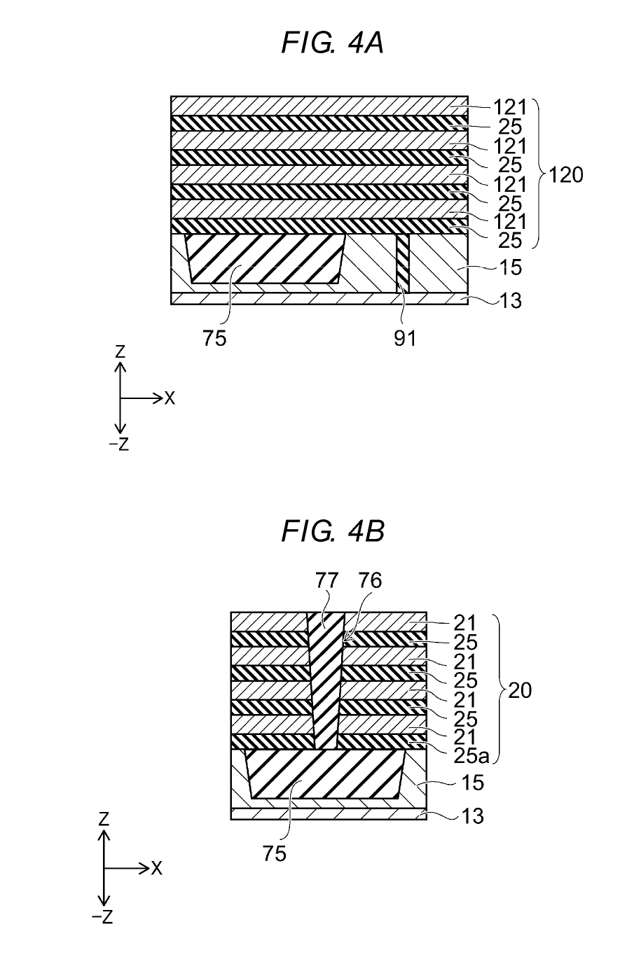

Next, as shown in FIG. 4A, a first stacked body (hereinafter referred to as stacked body 120) where insulation films 25 and conductive films 121 are alternately formed in a stack, one over another on the back gate layer 15 and the sacrificial film 75. As shown in FIG. 4A, the stacked body 120 includes the plurality of conductive films 121 and the plurality of insulation films 25, and the insulation film 25 is interposed between each pair of conductive films 121 arranged adjacent to each other in the Z direction.

The insulation film 25 is formed of a silicon oxide film, for example, and the conductive film 121 is formed of a p-type polysilicon film doped with Boron (B), for example. The insulation film 25 and the conductive film 121 may be formed using a plasma Chemical Vapor Deposition (CVD) method, for example.

Next, the stack of conductive films 121 and insulation films 25 are divided, by photolithography and etching processes, to form the second groove 76 which extends through the stacked body 120 to the sacrificial film 75 as is shown in FIG. 4B. Due to such processing, the conductive film 121 is divided into a plurality of word lines 21 disposed to either side, in the x direction, of the second groove 76. The first stacked body 120 is thus divided into a plurality of second stacked bodies (hereinafter referred to as stacked bodies 20).

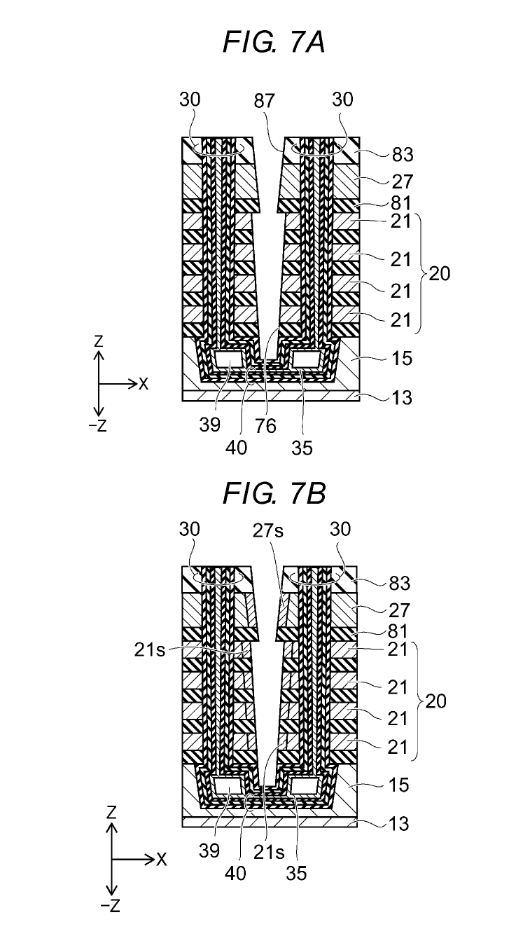

Further, as shown in FIG. 4B, a second insulation film (hereinafter referred to as an insulation film 77) is embedded into the inside of the second groove 76. The insulation film 77 has the selectivity of etching with respect to the insulation film 25, the word line 21 and the memory film 40 (see FIG. 7A), such that it is preferentially etched in comparison to etching of the insulation film 25, the word line 21 and the memory film 40. The insulation film 77 is formed of a silicon nitride film, for example.

The second groove 76 may be formed to have a depth such that all the conductive films 121 are divided by the second groove 76, and the second groove 76 extends therethrough and through the insulation film 25a formed between the back gate layer 15 and the conductive film 121 at the lowermost layer of the stacked body 120. However, to take into account irregularities in etching depth for every wafer and on a wafer surface, it is difficult to stop etching of the second groove 76 at a depth that the second groove 76 consistently extends through the insulation film 25a. On the other hand, if the sacrificial film 75 is divided by the second groove 76, in succeeding steps, it is not possible to make two memory holes communicate with each other.

To facilitate the formation of the second groove 76 by etching, for example, an etching stop layer or a conductive film having a thickness which enables the conductive film to absorb irregularities in etching may be inserted between the back gate layer 15 and the insulation film 25a. However, in these methods, etching of the memory holes which communicate with the sacrifice film 75 becomes difficult.

In view of the above, this embodiment allows the formation of the second groove 76 such that the second groove extends through the insulation film 25a and has a depth and may extend inwardly of the sacrificial film 75. Further, a depth or thickness, in the −Z direction, of the sacrificial film 75 (that is, a depth of the sacrificial film 75 in the first groove 73) is larger than a range of differences in depth of the second groove 76 as a result of etching differences across an entire substrate undergoing the trench etch process to form grove 76. Due to such constitution, differences in the etched depth of the second groove 76 may be tolerated, and it is possible to consistently configure two memory holes to communicate with each other through the location of the second groove 76.

Next, the insulation film 81, a conductive layer 127 which constitutes the selector gates 27, and the insulation film 83 are formed on the stacked bodies 20 and the insulation film 77. Then, memory holes 85 which penetrate the conductive layer 127 and the stacked bodies 20 in the −Z direction from an upper surface of the insulation film 83 and reach the sacrificial film 75 are formed as shown in FIG. 5A. The lower ends of the memory holes 85 extend to the location of the sacrifice film 75 in the second groove 76, and the sacrifice film 75 is thus exposed to bottom portions of the memory holes 85.

The memory hole 85 may be formed by etching the insulation film 83, the conductive layer 127, the insulation film 81 and the stacked bodies 20 using an RIE (Reactive Ion Etching) method after forming an etching mask not shown in the drawing on the insulation film 83, for example.

Next, the sacrificial film 75 embedded in the second groove in the back gate layer 15 is selectively etched through the memory holes 85. For example, when the sacrificial film 75 is formed of a non-doped polysilicon film, the sacrificial film 75 may be etched by wet etching using an alkaline reagent solution such as a KOH (potassium hydroxide) solution.

Due to such processing, as shown in FIG. 5B, the sacrifice film 75 is selectively removed, and the first groove 73 is reproduced in the back gate layer 15. Further, the two memory holes 85 are communicated with each other through the first groove 73.

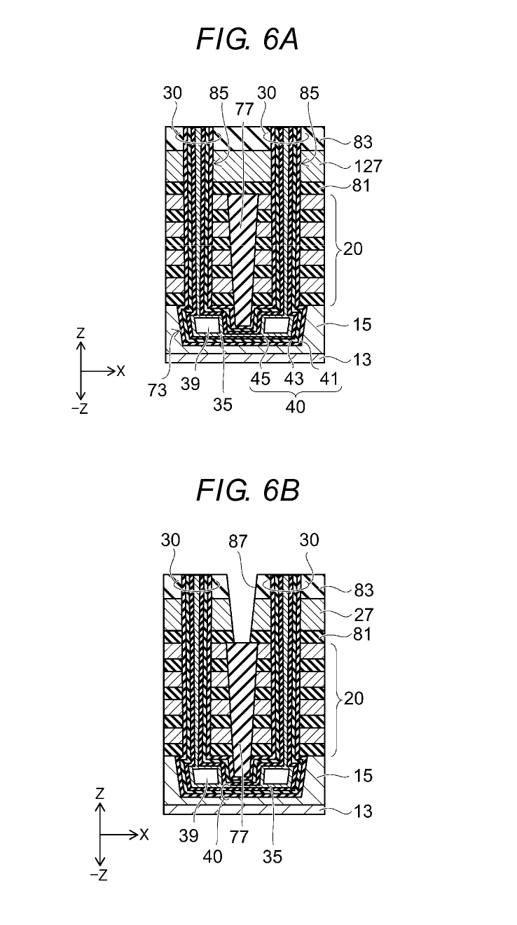

Next, as shown in FIG. 6A, the memory film 40 which covers inner walls of the memory holes 85 and an inner surface of the first groove 73 is formed, and the semiconductor film 35 which covers the memory film 40 is formed on the memory film 40.

The memory film 40 includes: the silicon oxide film 41 which is formed on the inner walls of the memory holes 85 and the inner surface of the first groove 73; the silicon nitride film 43 which is formed on the silicon oxide film 41; and the silicon oxide film 45 which is formed on the silicon nitride film 43, for example.

The semiconductor film 35 is formed of a polysilicon film which is formed on the silicon oxide film 45, for example. The semiconductor film 35 may be formed such that inner spaces of the memory holes 85 are completely filled with the semiconductor film 35. In the first groove 73, the semiconductor film 35 may have a hollow structure where a gap remains at the center thereof below each memory hole 85, or may have a structure where a core film which is an insulation film is formed in the hollow portion.

Next, as shown in FIG. 6B, a third groove 87 which communicates with the insulation film 77 at an upper surface of the insulation film 83 is formed. The third groove 87 extends in the Y direction and divides the conductive layer 127 into the plurality of selector gates 27.

Next, as shown in FIG. 7A, the insulation film 77 is selectively etched, through the third groove 87, thus reproducing the second groove 76 so that ends of the word lines 21 are exposed to the inside of the second groove 76.

Next, as shown in FIG. 7B, end portions 21s of the word lines 21 and end portions 27s of the selector gates 27 are converted into a silicide.

For example, a nickel (Ni) film is formed on the inner surface of the second groove 76 and the inner surface of the third groove 87 and, thereafter, heat treatment is applied to the nickel film. Due to such processing, nickel silicide is formed on the end portions 21s of the word lines 21 and the end portion 27s of the selector gates 27. On the other hand, nickel which is adhered to the end surfaces of the insulation films 25, 81 and 83 does not react with the respective insulation films and is maintained in the form of elemental nickel. Accordingly, the nickel adhered to the end surfaces of the insulation films 25, 81 and 83 may be removed using wet processing, for example, after forming the nickel silicide on the end portions 21s of the word lines 21.

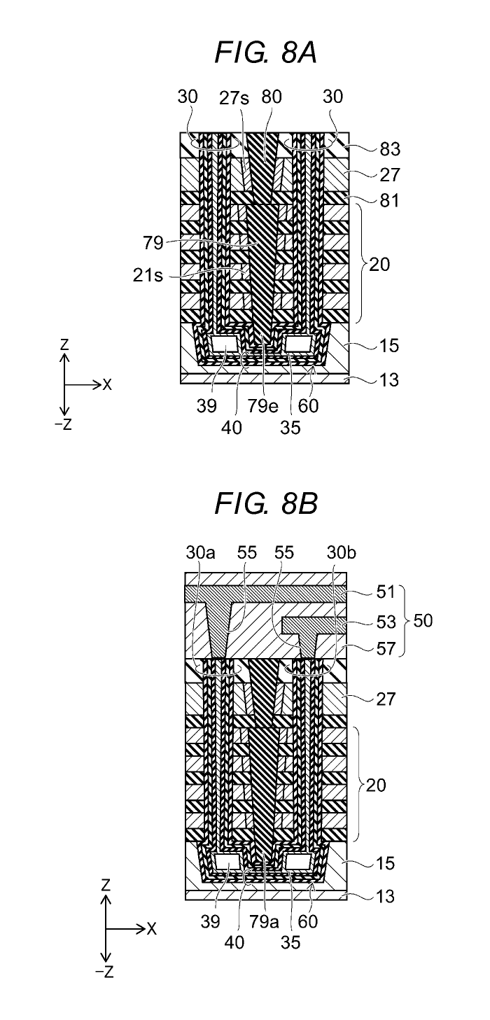

Next, as shown in FIG. 8A, a third insulation film (insulation film 79) is embedded into the inside of the second groove 76 and the third groove 87. The insulation film 79 is formed of a silicon oxide film or a silicon nitride film, for example. An end portion 79e which projects more in the −Z direction than the ends of the semiconductor pillars 30 which are brought into contact with the connection portion 60 is formed on a bottom portion of the second groove 76.

Next, as shown in FIG. 8B, the wiring layer 50 is formed on the insulation film 83 thus completing the non-volatile storage device 100. The wiring layer 50 includes the bit lines 51, the source lines 53 and the interlayer insulation film 57. The bit lines 51 are electrically connected to semiconductor pillars 30a via the contact plugs 55. The source lines 53 are electrically connected to semiconductor pillars 30b. The semiconductor pillars 30a and the semiconductor pillars 30b are electrically connected to each other via the connection portion 60.

As has been explained heretofore, in this embodiment, irregularities in depth of the slit (second groove 76) for dividing the conductive film 121 into the word lines 21 may be absorbed by the sacrifice film 75 for forming the connection portion 60. That is, the sacrifice film 75 is formed to have a thickness which enables the sacrifice film 75 to absorb irregularities in depth of the slit and the sacrifice film 75 is not divided by the slit. Further, the back gate layer 15 is formed such that a thickness of the back gate layer 15 is larger than a thickness of the sacrifice layer 75. Due to such a constitution, the difficulty in control of depth in etching the slit and in control of depth of the memory hole which communicates with the sacrifice film 75 may be decreased. Further, manufacturing efficiency of the non-volatile storage devices and a manufacturing yield of non-volatile storage devices may be enhanced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid state storage device, comprising:
a first gate;
a plurality of conductive layers having insulating layers therebetween, one of the insulating layers located on the first gate;
an interconnection region extending inwardly of the first gate;
a first semiconductor layer extending through the plurality of conductive layers and insulating layers;
a second semiconductor layer extending through the plurality of conductive layers and insulating layers;
a third semiconductor layer extending through the interconnection region and electrically connecting the first and second semiconductor layers; and
an insulator extending through the plurality of conductive layers and insulating layers at a location intermediate of the first and second semiconductor layers, and also extending inwardly of the interconnection region.

2. The solid state storage device of claim 1, wherein the first gate is formed on a base, and includes an enlarged portion and a thinned portion, the thinned portion extending between the base and the third semiconductor layer.

3. The solid state storage device of claim 2, wherein the third semiconductor layer extends between the insulator and the thinned portion of the first gate.

4. The solid state storage device of claim 2, further comprising a charge storage layer extending between the first and second semiconductor layers and the plurality of conductive layers.

5. The solid state storage device of claim 4, further comprising an insulating layer located between the first and second semiconductor layers and the charge storage film, and between the charge storage film and the plurality of conductive layers.

6. The solid state storage device of claim 1, wherein, within the interconnection region, the third semiconductor layer surrounds a void.

7. The solid state storage device of claim 6, wherein a first void extends at least partially between the base and the first semiconductor layer and a second void extends at least partially between the base and the second semiconductor layer.

8. The solid state storage device of claim 6, wherein the insulator extends at least partially inwardly of a gap between the first void and the second void.

9. The solid state storage device of claim 1, wherein the memory is a non-volatile memory.

10. A non-volatile storage device comprising:
a first conductive layer;
a plurality of stacked bodies which are arranged parallel to each other on the first conductive layer, each stacked body including a plurality of conductive films stacked on the first conductive layer;
first and second semiconductor pillars which penetrate the plurality of stacked bodies in a first direction extending from an upper surface of the plurality of the stacked bodies toward the first conductive layer, the semiconductor pillars including a semiconductor film which extends in the first direction and a memory film formed between the stacked body and the semiconductor film;
a connection portion which is formed in the first conductive layer and electrically connects the first and second semiconductor pillars extending thorough the stacked bodies; and
an insulation layer which is provided between the two stacked bodies arranged to each other and includes an end portion which projects inwardly of the connection portion in the first direction further than the semiconductor pillars.

11. The non-volatile storage device of claim 10, wherein
a thickness of the first conductive layer in the first direction is larger than a largest thickness of the connection portion in the first direction, and
the largest thickness of the connection portion is larger than a depth of the end portion of the insulation layer extending inwardly of the connection portion in the first direction.

12. The non-volatile storage device of claim 10, wherein
a thickness in the first direction of a portion of the connection portion formed between the end portion of the insulation layer and the first conductive layer is smaller than a thickness in the first direction of a portion of the connection portion which is in contact with the semiconductor pillar.

13. The non-volatile storage device of claim 10, wherein
the connection portion includes a portion of the semiconductor film which electrically connects the two semiconductor pillars to each other and a portion of the memory film which is formed between the first conductive layer and a portion of the semiconductor film.

14. The non-volatile storage device of claim 10, wherein
a thickness in the first direction between the end portion of the insulation film and the first conductive layer adjacent the end portion is more than two times larger than a film thickness of the memory film.

15. The non-volatile storage of claim 10, wherein the first conductive layer is a gate layer.

16. The non-volatile storage of claim 15, wherein the conductive films constitute word lines.

17. The non-volatile storage of claim 13, wherein the end portion of the insulation layer is in contact with the portion of the memory film which is formed between the first conductive layer and the portion of the semiconductor film.

18. The non-volatile storage of claim 13, wherein the connection portion includes a void surrounded by the portion of the semiconductor film.

19. A method of manufacturing a non-volatile storage device comprising:
forming a first groove in a first conductive layer;
embedding a sacrificial film in the first groove;
forming a first stacked body, which includes a plurality of first insulation films and a plurality of conductive films, on the first conductive layer and the first sacrificial film, the plurality of first insulation films and conductive films being alternately stacked one over the other;
forming a second groove extending from an upper surface of the first stacked body into the sacrificial film, the second groove dividing the first stacked body into a plurality of second stacked bodies;
embedding a second insulation film in the second groove;
forming a memory hole through the plurality of respective second stacked bodies to the sacrificial film;
selectively etching the sacrificial film via the memory hole to reestablish the first groove in an open condition; and
forming a memory film which covers an inner wall of the memory hole and the inner walls of the first groove, and a semiconductor film disposed on the memory film.
